(19) United States
(12) Patent Application Publication
(10) Pub. No.: US 2008/0050883 A1
(43) Pub. Date: Feb. 28, 2008

(54) HETROJUNCTION BIPOLAR TRANSISTOR (HBT) WITH PERIODIC MULTILAYER BASE

(75) Inventor: Darwin G. Enicks, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/467,480

(22) Filed: Aug. 25, 2006

(51) Int. Cl. H01L 21/331

(52) U.S. Cl. 438/312

(57) ABSTRACT

A method and resulting electronic device utilizing a periodic multi-layer (ML) and/or superlattice (SL) structures in the base of a SiGe heterojunction bipolar transistor (HBT) is disclosed. The SL is a special case of an ML, in which layers that are chemically different from adjacent neighbors are successively repeated. The use of the ML in electronic and photonic devices is enables strategic engineering of the energy band gap and carrier mobilities. Principles disclosed herein relate to npn- and pnp-type SiGe HBTs as well as HBTs made with other compound semiconductor materials (e.g., other Group III-V or II-VI materials). Additionally, technology and methods disclosed herein benefit other devices types such as, for example, metal oxide semiconductor field effect transistors (MOSFETs), high electron mobility transistors (HEMTs), high hole mobility transistors (HHMTs), bipolar junction transistors (BJTs), and FINFETs.

### TECHNICAL FIELD

The invention generally relates to methods of fabrication of integrated circuits (ICs). More specifically, the invention is a method of fabricating multi-layer heterojunction bipolar transistors utilizing compound semiconducting materials.

### BACKGROUND ART

Fabrication of conventional heterojunction bipolar transistors (HBT) involves using individual layers of homogeneous materials. An example is a modern silicon-germanium heterojunction bipolar transistor (SiGe HBT). The emitter of a SiGe HBT is typically constructed of silicon with either an n-type or p-type polarity, the base region is constructed of SiGe with either n- or p-type polarity, and the collector is made of either p- or n-type silicon.

Using SiGe in the base region improves device performance in several ways: (1) The SiGe provides an energy band offset at the base-emitter, BE, junction for enhanced electron injection resulting in higher collector current densities, J_{C}. (2) Base resistance, r_{B}, is reduced due to enhanced hole carrier mobility (for an npn HBT with boron dopant in the base). (3) Dopant diffusion is minimized in SiGe resulting in a nanometer scale neutral base width (i.e., less than 100 nm); the nanometer scale base width makes possible a greatly reduced transit time, τ_{b} (these factors are especially prominent when boron is the dopant material). (4) Ge can be graded to provide a built-in drift field to enhance carrier velocity and further reduce τ_{b}. (5) Ge can also be graded into the collector region to increase the base-collector breakdown voltage, BV_{CB0}, which also increases the collector-emitter breakdown, BV_{CE0}.

These enhancements equate to improved performance with regard to important figures of merit such as unity gain cutoff frequency, f_{T}, max oscillation frequency, fₘₐₓ, minimum noise figure, NFₘᵢₙ, and current gain, β. Additionally, device efficiency is enhanced resulting in reduced power consumption.

HBT technology overall is advancing rapidly. The technology evolution with respect to f_{T} and fₘₐₓ is illustrated with reference to FIG. 1. FIG. 1 depicts first through fourth generations of HBT devices and shows a general evolution of SiGe and SiGeC HBT performance. Currently, devices with an f_{T} greater than 300 GHz are now a reality. An important constraint for a designer of high speed, low noise devices is a ratio of fₘₐₓ/f_{T}, which must be maintained at values greater than 1.0 in most applications, and greater than 1.2 in many cases. As HBT performance continues to increase, an ability to maintain an fₘₐₓ/f_{T} ratio greater than 1.0 becomes increasingly difficult. The difficulty arises from the balance between high f_{T} and low r_{B}, and also low collector-base capacitance, C_{CB}. High f_{T} devices necessarily employ a very thin base region (W_{b}). However, as base regions become thin, r_{B} becomes high. As r_{B} increases, fₘₐₓ is diminished. Maximum oscillation frequency, fₘₐₓ, is related to r_{S} through the following equation:

$${f}_{max} = \sqrt{\frac{{f}_{r}}{8 π {r}_{B} {C}_{CB}}}$$

wherein C_{CB} is collector-base capacitance and, as described above, r_{B} is device base resistance.

As W_{b} becomes thin, the total dose of dopant that can be added to the lattice space is reduced. The lower doses of dopant not only result in an elevated r_{B}, but also in very high current gains, β. Current gain is a simple ratio between collector current, I_{C}, and the base current, I_{B}:

$$β = \frac{{I}_{C}}{{I}_{B}}$$

I_{C} by itself is a function of many factors. However, assuming all other factors are held constant, I_{C} is inversely proportional to both W_{b} and the total concentration of base dopant, N_{ab}. The product of W_{b} and N_{ab} gives the approximate dose of dopant in the base region (assuming a continuously doped base region).

Dose≡N_{ab}W_{b}

One skilled in the art will recognize that secondary ion mass spectrometry (SIMS) may quantify the elemental concentration of dopant and that dose can also be estimated by integrating the total concentration as a function of profile depth.

Collector current density, J_{C} (units of amps/μm²), is inversely proportional to Dose (defined immediately above) as defined in the denominator of the first term:

$${J}_{C} = \frac{{qD}_{nb}}{{N}_{ab} {W}_{b}} ( {e}^{\frac{{qV}_{be}}{kT}} - 1 ) {n}_{i}^{2} ( {e}^{\frac{Δ {E}_{gb}^{app}}{kT}} ) ( γ η [ \frac{{E}_{g} ( grade )}{kT} ] ) {e}^{\frac{Δ {E}_{g} ( 0 )}{kT}}$$

and I_{C} may be related to the collector current density by:

I_{C}=J_{C}A_{E}

where A_{E} is the emitter area (μm²).

Based on the relationship of β defined as the ratio of collector to base current, the base current is directly proportional to N_{ab} added to the base region, and also to W_{b}. Consequently, a lower dose and/or reduced W_{b} equates to a reduction in I_{B}. Maintaining very narrow boron doped region in the SiGe HBT, which defines W_{b}, is made possible due to the reduced rate of boron diffusion. As a result of the foregoing relationships, an increase in I_{C} and reduction in I_{B} equates to a significant increase in β.

High current gains are generally beneficial. However, if too high, the elevated current gain results in substantial reductions in collector-emitter breakdown voltage, BV_{CE0}. BV_{CE0} is related to the n^{th} root of β and also to the collector-base breakdown voltage, BV_{CB0}.

$${BV}_{CE 0} = \frac{{BV}_{CE 0}}{{β}^{\frac{1}{n}}}$$

### Typically, 3<n<6. An exact value for ‘n’ is typically determined experimentally.

Therefore, what is needed is a method which allows advances with respect to f_{T}, but that allows a simultaneous reduction in r_{B}, an increase in fₘₐₓ and ultimately an increased fₘₐₓ/f_{T} ratio. This technology should provide extra degrees of freedom for the device designer to tune f_{T}/fₘₐₓ, β, r_{B}, BV_{CE0}, I_{C}, and I_{B}. The technology should also utilize a standard semiconductor manufacturing equipment installed base for optimum manufacturability.

### SUMMARY

In one exemplary embodiment, the present invention is a method for fabricating an electronic device where the method includes providing a semiconductor substrate having a first surface, doping at least a portion of the first surface, and forming a first compound semiconductor film over the first surface of the substrate. The first compound semiconductor film is doped with a first dopant type and a second compound semiconductor film is formed over the first compound semiconductor film. A third compound semiconductor film is formed over the second compound semiconductor film and the third compound semiconductor film being doped with a second dopant type. In various other embodiments, additional compound semiconductor film layers are added, in selected ways, to the basic film stack described. The compound semiconductor film layers may be comprised of SiGe with varying levels of germanium and various combinations of doped and undoped (i.e., substantially intrinsic) compound semiconductor film layers.

In another exemplary embodiment, the present invention is a method of fabricating a heterojunction bipolar transistor where the method includes forming a collector region in a substrate, the substrate being selected to have at least an uppermost portion comprised of an elemental semiconductor. The elemental semiconductor may be silicon. A multi-layer base region is formed over the collector region. Formation of the multi-layer base region includes forming a doped first silicon-germanium film over the first surface of the substrate and forming a second silicon-germanium film over the first silicon-germanium film. The second silicon-germanium film is selected to have a high concentration of germanium. A doped third silicon-germanium film is formed over the second silicon-germanium film and an elemental semiconductor layer is chosen to act as an emitter and is formed over the third silicon-germanium film. In various other embodiments, additional compound semiconductor film layers, such as additional SiGe layers, are added, in selected ways, to the basic film stack described. The SiGe layers may be formed with varying levels of germanium and various combinations of doped and undoped (i.e., substantially intrinsic) SiGe layers.

In another exemplary embodiment, the present invention is an electronic device which includes a substrate having at least an upper portion being comprised of a semiconductor material. The substrate may be, for example, a silicon wafer, an SOI wafer, or other semiconductor wafer. The substrate may also be comprised of various materials such as a quartz reticle with a polysilicon layer deposited and annealed to re-crystallize the polysilicon to single-crystal silicon. Over the substrate, a first doped compound semiconductor film is disposed with a second compound semiconductor film disposed over the first compound semiconductor film. The second compound semiconductor film is configured to act as a quantum well layer. A third doped compound semiconductor film is disposed over the second compound semiconductor film and a cap layer comprised of a semiconductor material is disposed over the third doped compound semiconductor film. In various other embodiments, additional compound semiconductor film layers, such as additional SiGe layers, are added to the basic film stack described. The SiGe layers may be formed with varying levels of germanium, in various profiles of germanium, and with added various combinations of doped and undoped (i.e., substantially intrinsic) SiGe layers.

In another exemplary embodiment, the present invention is a heterojunction bipolar transistor which includes a collector layer made substantially of an elemental semiconductor and contained in at least an upper portion of a substrate. The substrate may be, for example, a silicon wafer, and SOI wafer, or other semiconductor wafer. The substrate may also be comprised of various materials such as a quartz reticle with a polysilicon layer deposited and annealed to re-crystallize the polysilicon to single-crystal silicon. Over the substrate, an emitter layer made substantially of an elemental semiconductor is disposed. A multi-layer base is disposed over the emitter layer. The multi-layer base is comprised substantially a first doped silicon-germanium layer and a second silicon-germanium layer disposed over the first silicon-germanium layer. The second silicon-germanium layer is configured to act as a quantum well layer and a third doped silicon-germanium layer disposed over the second silicon-germanium layer. In various other embodiments, additional SiGe layers are added to the basic film stack described. The SiGe layers may be formed with varying levels of germanium, in various profiles of germanium, and with added various combinations of doped and undoped (i.e., substantially intrinsic) SiGe layers. The various SiGe layers allow tuning parameters of the device for specific performance characteristics.

### BRIEF DESCRIPTION OF THE DRAWINGS

FIG. 1 is a graph relating maximum oscillation frequency to gain cutoff frequency for prior art HBT devices.

FIG. 2 is an exemplary embodiment of a periodic multi-layer (ML) structure.

FIG. 3 is a graph showing dopant dependent carrier mobility in silicon, germanium, and gallium arsenide.

FIG. 4 is a cross-section of an exemplary embodiment of a remote carbon film stack.

FIG. 5A is a cross-section of an exemplary embodiment of a SiGe ML film stack.

FIG. 5B is a cross-section of an exemplary embodiment of the SiGe ML film stack of FIG. 5A along with the film stack's associated energy band gap diagram.

FIG. 6 is a cross-section of an exemplary embodiment of another SiGe ML film stack along with the film stack's associated energy band gap diagram.

FIG. 7 is a cross-section of an exemplary embodiment of another SiGe ML film stack along with the film stack's associated energy band gap diagram.

FIG. 8 is a cross-section of an exemplary embodiment of another SiGe ML film stack along with the film stack's associated energy band gap diagram.

FIG. 9 is a cross-section of an exemplary embodiment of another SiGe ML film stack along with the film stack's associated energy band gap diagram.

FIG. 10 is a graph indicating sheet resistance as a function of carbon dose levels for various doping methods and multi-layer film stacks.

FIGS. 11-15 indicate various types of germanium profiles for percentage of germanium in silicon as a function of base region depth.

FIG. 16 is a graph indicating critical thickness of pseudomorphic SiGe on silicon as a function of either percentage or mole fraction of germanium in the silicon lattice.

### DETAILED DESCRIPTION

Critical shortcomings in the prior art exist that must be overcome to realize further benefits of the advantages of SiGe HBTs. The following disclosure relates specifically to an npn-type SiGe HBT, but the principles involved also relates to pnp-type SiGe HBTs as well as HBTs made with other compound semiconductor materials (e.g., other Group III-V or II-VI materials). Additionally, technology and methods disclosed herein benefits other devices types such as, for example, metal oxide semiconductor field effect transistors (MOSFETs), high electron mobility transistors (HEMTs), high hole mobility transistors (HHMTs), bipolar junction transistors (BJTs), and FINFETs.

The periodic multi-layer (ML) and/or superlattice (SL) have been known for other applications for some time. However, the use of an ML in the base of a SiGe HBT represents a new utilization of this technology. The SL is a special case of an ML, in which layers that are chemically different from adjacent neighbors are successively repeated. Therefore, an SL is a periodic ML. The use of the ML in electronic and photonic devices is important since it enables strategic engineering of the energy band gap and carrier mobilities.

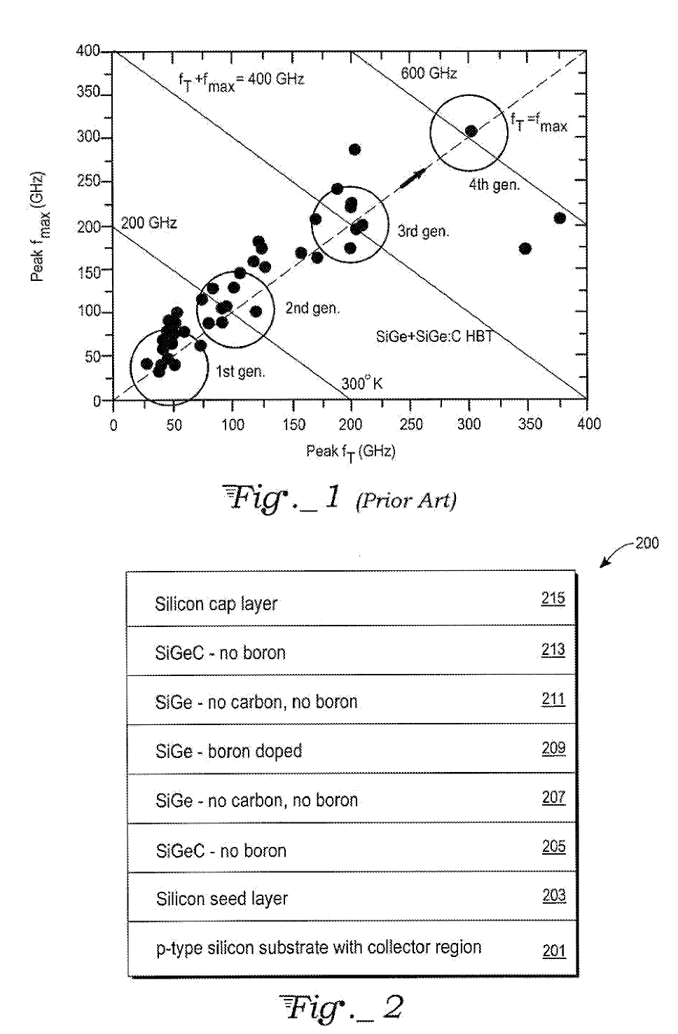

FIG. 2 provides an exemplary embodiment of a periodic ML structure 200. The exemplary periodic ML structure 200 includes a p-type silicon substrate with a doped collector region 201, a silicon seed layer 203, a first SiGeC layer 205 without boron (B), and a first SiGe layer 207 without either boron or carbon. The first SiGe layer 207, being undoped, provides for two-dimensional hole gas (2DHG) transport. The 2DHG forms at the heterointerface and physically comprises a very narrow undoped SiGe layer (no carbon, no boron) that has a higher Ge concentration than surrounding SiGe layers. The increased Ge concentration results in a reduction in energy band gap resulting in a quantum well effect. Energy band gap effects for various ML film types are discussed in detail, below.

A second SiGe layer 209 is boron doped and a third SiGe layer 211 is similar to the first SiGe layer 207 in that the third SiGe layer 211 has neither a carbon nor a boron doping. The third SiGe layer 211 provides for a second 2DHG transport region. A second SiGeC layer 213 is similar to the first SiGeC layer 205 in that the second SiGeC layer 213 has no boron doping. A silicon cap layer 215 completes the exemplary periodic ML structure 200. The exemplary periodic ML structure 200 thus provides a film stack in which undoped SiGe is alternated with SiGeB and SiGeC.

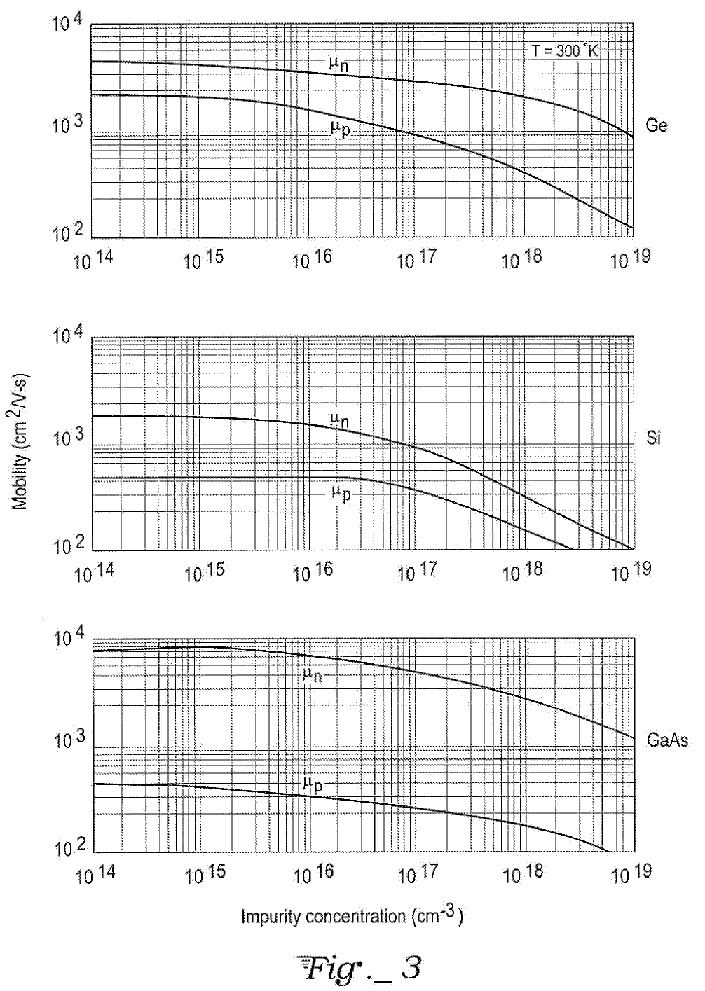

Undoped SiGe layers have a higher intrinsic carrier mobility than either a SiGeB or SiGeC layer due to less alloy and lattice scattering from the addition of boron or carbon. FIG. 3 illustrates dopant dependent mobility in silicon, germanium, and gallium arsenide (GaAs). The same type of relationship between dopant concentration and mobility holds true in SiGe semiconductors as well. However, due to the very low concentration of carriers (only intrinsic carriers), the conductivity of undoped (i.e., intrinsic) SiGe is very low compared to SiGeB. This conductivity difference can be elucidated from the conductivity equation. The conductivity equation states that:

σ=e(μₑn+μₕp)

where electron and hole mobilities are μₑ and μₕ respectively, n and p are electron and hole concentrations due to ionized donor (N_{D}) and acceptor ion (N_{A}) concentrations respectively, and the carrier charge, e, is 1.6×10⁻¹⁹ Coulomb. The resistivity (ρ=σ⁻¹) with N_{A}>>N_{D} may be calculated with μₑ and n neglected. Therefore, for a given thickness of SiGe film t_{SiGe}, a four point probe sheet resistance measurement (Rs in units of Ω/□) of a p-type or boron (B) doped film is:

$$Rs = \frac{ρ}{{t}_{siGe}} = \frac{1}{e {μ}_{h} {pW}_{b}}$$

### Multi-Layer and/or Superlattice SiGe Films

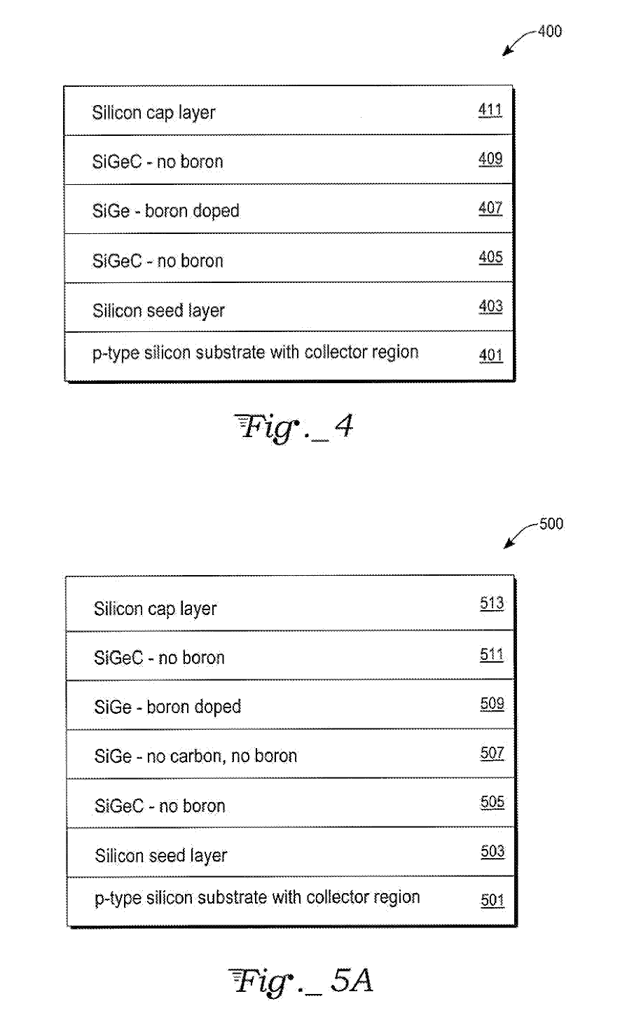

There are a number of advantageous film structures that can be produced with ML and/or SL (hereinafter, “ML and/or SL” are simply be referred to as “ML” unless otherwise noted). For example, FIG. 4 illustrates an exemplary embodiment of a remote carbon film stack 400. Techniques for producing the remote carbon film stack 400 are currently patent pending and assigned to the same assignee as the present application (Atmel Corporation, Ser. No. 11/166,287, filed Jun. 23, 2005). Briefly, the remote carbon film stack 400 may be used for an HBT device and includes a p-type silicon substrate with a doped collector region 401, a silicon seed layer 403, a first SiGeC layer 405 without boron, a boron doped SiGe layer 407, a second SiGeC layer 409 without boron, and a silicon cap layer 411.

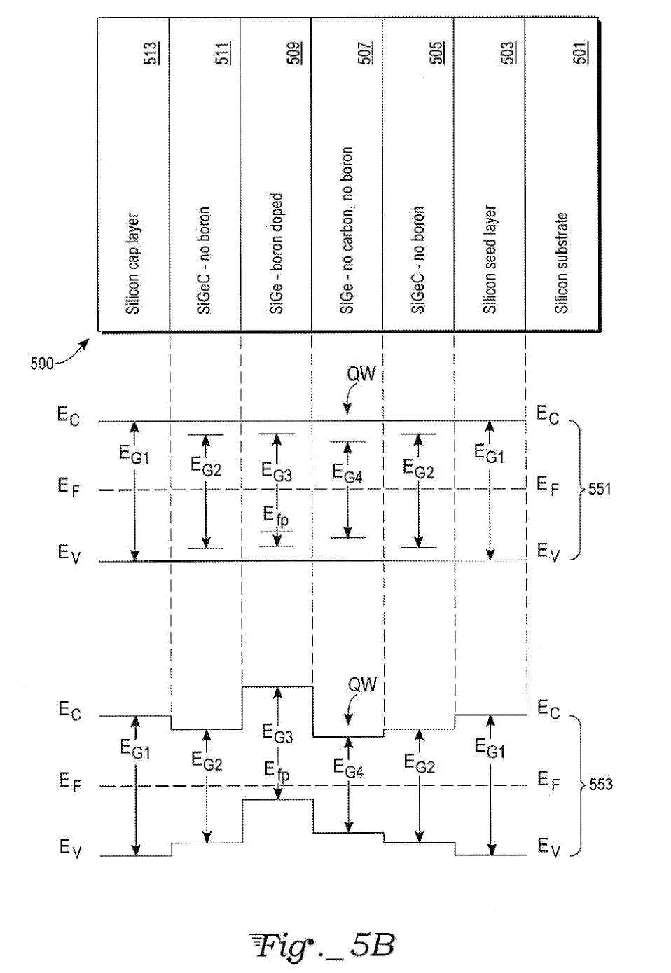

FIG. 5A illustrates another exemplary SiGe ML film stack 500. The exemplary SiGe ML film stack 500 includes a p-type silicon substrate with a doped collector region 501, a silicon seed layer 503, a first SiGeC layer 505 without boron, a first SiGe layer 506 with neither boron nor carbon doping, a second SiGe layer 509 with boron doping, a second SiGeC layer 511 without boron, and a silicon cap layer 513. The main difference between the remote carbon film stack 400 of FIG. 4 and the SiGe ML film stack 500 of FIG. 5A lies in the provision of a high mobility layer (undoped SiGe) next to the dopant-enriched layer (SiGeB) coupled with a SiGeC layer to prevent boron out-diffusion. The first SiGe layer 507 serves as a 2DHG layer.

FIG. 5B through FIG. 9 are energy band gap diagrams associated with various exemplary ML structures. A percentage of Ge in undoped SiGe layers (also referred to as the 2DHG layers) of the various exemplary ML structures of FIGS. 5B-9 is be greater than or equal to a percentage of Ge in surrounding layers of SiGeB and/or SiGeC. An increase in the percentage of Ge in the undoped SiGe layer provides a quantum well (QW) effect for greater confinement of carriers, in the form of a 2DHG, to the undoped SiGe region. From a quantum mechanical viewpoint, a carrier wave function has a greater probability of existing within the undoped SiGe layer, which represents a QW due to its reduced energy band gap (assuming it has more Ge than surrounding layers). Since the QW layer also has a higher hole mobility than surrounding layers, the conductivity of the 2DHG is enhanced. (A skilled artisan will recognize the QW and the 2DHG layers are references to the same layer.)

The first band gap energy diagram in each of the FIGS. 5B-9 indicates an energy structure of independent films of the ML film stack prior to the films being brought into contact with (i.e., formed next to) each other. Therefore, in the first band gap energy diagram, Fermi levels of each film are not forced into alignment. This first diagram is thus an idealization for visualization only and aids a skilled artisan in understanding and following the band alignment depicted in the second band gap energy diagram.

The second band gap energy diagram in each of the FIGS. 5B-9 depicts what happens once the films are grown. This view is of an ML structure in which the Fermi level alignment has been completed due to physical constraints for equilibrium of charge. This depiction represents an unbiased film (i.e., no potential applied). In the second diagram, the formation of the quantum well layers (E_{G4}) is plain. The formation of a QW only takes place if the percentage of Ge in this layer is greater than surrounding boron-doped layers. More Ge equates to a smaller E_{G}.

Energy band definitions employed herein are considered for ideal theoretical calculations and may vary in practical ML structures. Any energy band gap is also dopant dependent. Therefore, some layers that might be labeled as not having any polarity altering dopants have a slightly different band gap if doped with either a Group III or V semiconductor due to degenerate doping effects (very high doping). However, principles discussed and illustrated, which involve 2-dimensional hole gas (2DHG) and quantum well formation (QW) for the enhancement of the ML conductivity, do not change. Thus, the following definitions are employed with reference to FIGS. 5B-9:
E_{G1} is the energy band gap (EG) of silicon 1.11 eV)
E_{G2} is the energy band gap of silicon-germanium carbon (SiGeC), with no boron added (i.e., no B dopant). The band gap is dependent on the percentage of both Ge and Carbon.

E_{G3} is the energy band gap of SiGe doped with boron. The energy band gap is dependent on percentages of both Ge and boron.
E_{G4} is the energy band gap of undoped SiGe having neither carbon nor boron. The energy band gap is thus only dependent on the percentage of Ge. This undoped SiGe layer is also the 2DHG layer. If the percentage of germanium in this layer is greater than the Ge percentage of surrounding layers, then this layer becomes a QW layer.

The minimum energy band gap of silicon is 1.11 eV, while the minimum band gap of germanium is 0.67 eV. The lattice parameter differences (i.e., differences in unit cell side length) between Si and Ge are 5.43 Å and 5.67 Å respectively. Therefore, a blend of Ge with Si results in a film with an E_{G} and lattice parameter somewhere in-between the pure constituents.

With reference to FIG. 5B, the exemplary SiGe ML film stack 500 of FIG. 5A is shown turned sidewise to indicate a relative band gap for each of the layers. The exemplary SiGe ML film stack 500 is unbiased (e.g., no potential is applied). The first energy band gap diagram 551 indicates energy bands prior to Fermi level alignment. The second energy band gap diagram 553 indicates energy bands after Fermi level alignment. The first SiGe layer 507 with neither boron nor carbon doping is the 2DHG layer and aligns with the E_{G4} energy level which is the location of the quantum well (QW).

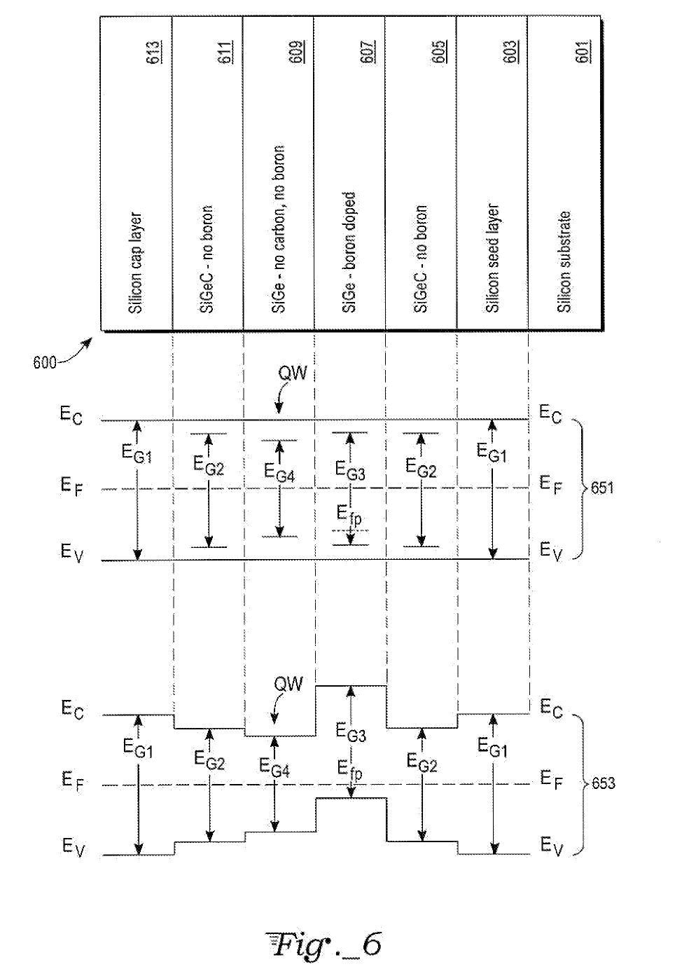

FIG. 6 illustrates another exemplary SiGe ML film stack 600 and related band gap energy diagrams 651, 653. The exemplary SiGe ML film stack 600 has a 2DHG layer above a SiGe with B doping layer. The film stack 600 includes a silicon substrate 601, a silicon seed layer 603, a first SiGeC layer 605 without boron, a first SiGe layer 607 with boron doping, a second SiGe layer 609 with high Ge content and neither boron nor carbon doping, a second SiGeC layer 611 without boron, and a silicon cap layer 613.

The exemplary SiGe ML film stack 600 is shown turned sidewise to indicate a relative band gap for each of the layers. The exemplary SiGe ML film stack 600 is unbiased (e.g., no potential is applied). The first energy band gap diagram 651 indicates energy bands prior to Fermi level alignment. The second energy band gap diagram 653 indicates energy bands after Fermi level alignment. The second SiGe layer 609 with high Ge content and neither boron nor carbon doping is the 2DHG layer and aligns with the E_{G4} energy level which is the location of the quantum well (QW).

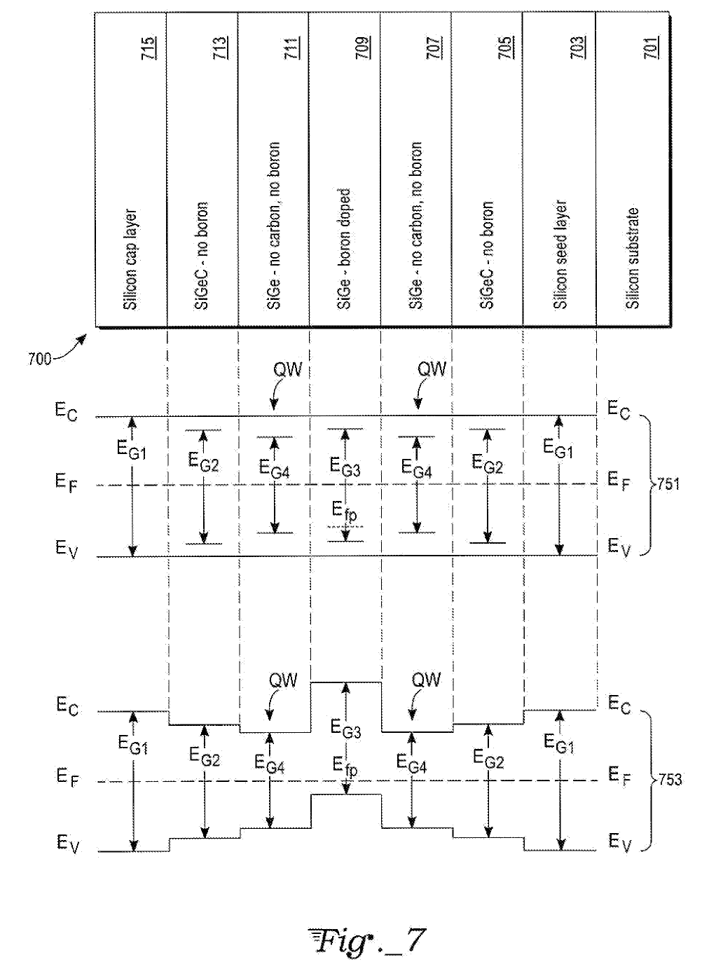

FIG. 7 illustrates another exemplary SiGe ML film stack 700 and related band gap energy diagrams 751, 753. The exemplary SiGe ML film stack 700 has a 2DHG layer on either side of a central SiGe with B doping layer. The film stack 700 includes a silicon substrate 701, a silicon seed layer 703, a first SiGeC layer 705 without boron, a first SiGe layer 707 with high Ge content and neither boron nor carbon doping, a second SiGe layer 709 with boron doping, a third SiGe layer 711 with high Ge content and neither boron nor carbon doping, a second SiGeC layer 713 without boron, and a silicon cap layer 715.

The exemplary SiGe ML film stack 700 is shown turned sidewise to indicate a relative band gap for each of the layers. The exemplary SiGe ML film stack 700 is unbiased (e.g., no potential is applied). The first energy band gap diagram 751 indicates energy bands prior to Fermi level alignment. The second energy band gap diagram 753 indicates energy bands after Fermi level alignment. The first 707 and third 711 SiGe layers with high Ge content and neither boron nor carbon doping are the two 2DHG layers. Each of the two 2DHG layers aligns with E_{G4} energy levels which are locations of the quantum wells (QW).

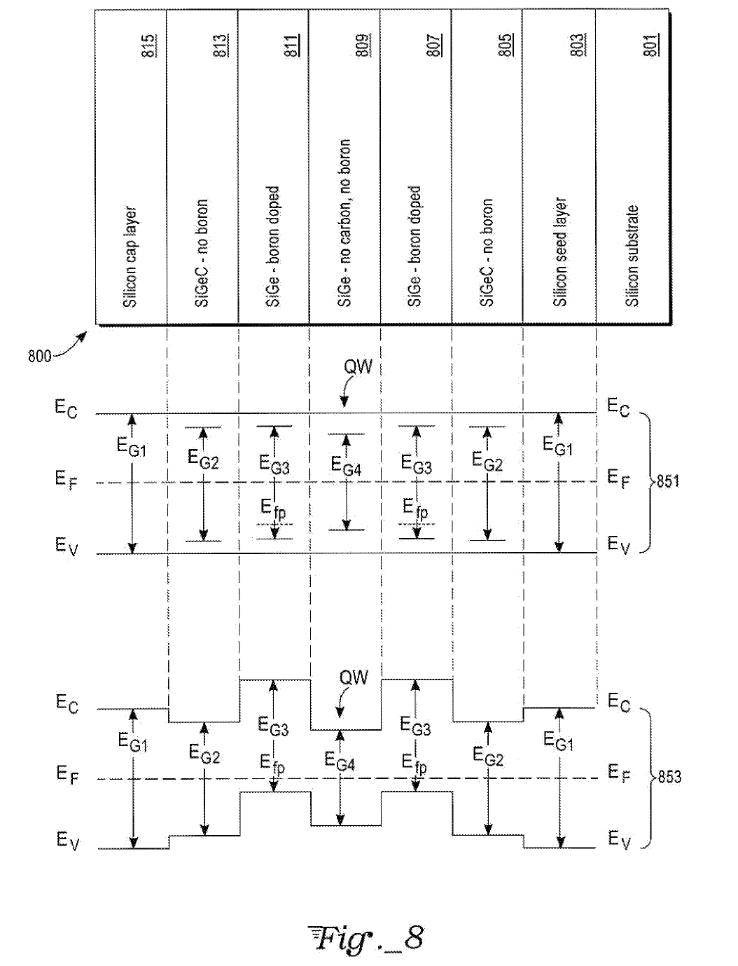

FIG. 8 illustrates another exemplary SiGe ML film stack 800 and related band gap energy diagrams 851, 853. The exemplary SiGe ML film stack 800 has a 2DHG layer sandwiched between two SiGe with B doping layers; the SiGe with B doping layers are adjacent to SiGe diffusion blocking layers. The film stack 800 includes a silicon substrate 801, a silicon seed layer 803, a first SiGeC layer 805 without boron, a first SiGe layer 807 with boron doping, a second SiGe layer 809 with high Ge content and neither boron nor carbon doping, a third SiGe layer 811 with boron doping, a second SiGeC layer 813 without boron, and a silicon cap layer 815.

The exemplary SiGe ML film stack 800 is shown turned sidewise to indicate a relative band gap for each of the layers. The exemplary SiGe ML film stack 800 is unbiased (e.g., no potential is applied). The first energy band gap diagram 851 indicates energy bands prior to Fermi level alignment. The second energy band gap diagram 853 indicates energy bands after Fermi level alignment. The second SiGe layer 809 with high Ge content and neither boron nor carbon doping is the 2DHG layer and aligns with the E_{G4} energy level which is the location of the quantum well (QW).

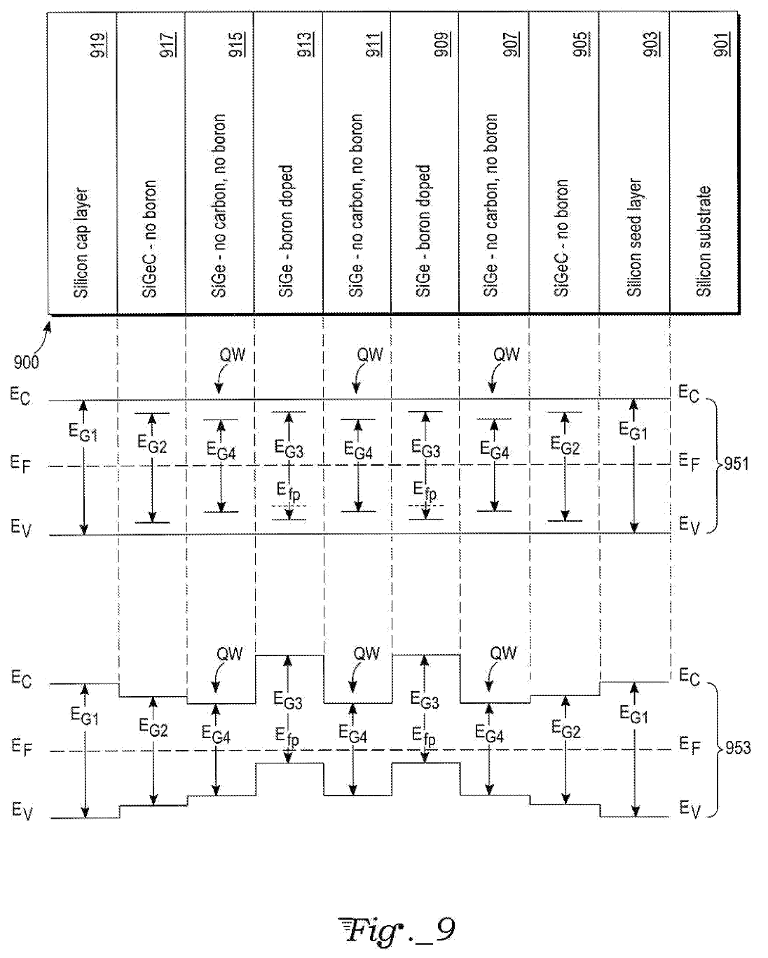

FIG. 9 illustrates another exemplary SiGe ML film stack 900 and related band gap energy diagrams 951, 953. The exemplary SiGe ML film stack 900 has three alternating 2DHG layers with two SiGe with B doping layers sandwiched between; SiGeC diffusion blocking layers are adjacent to and outside of this five layer sandwich. The film stack 900 includes a silicon substrate 901, a silicon seed layer 903, a first SiGeC layer 905 without boron, a first SiGe layer 907 with high Ge content and neither boron nor carbon doping, a second SiGe layer 909 with boron doping, a third SiGe layer 911 with high Ge content and neither boron nor carbon doping, a fourth SiGe layer 913 with boron doping, a fifth SiGe layer 915 with high Ge content and neither boron nor carbon doping, a second SiGeC layer 917 without boron, and a silicon cap layer 919.

The exemplary SiGe ML film stack 900 is shown turned sidewise to indicate a relative band gap for each of the layers. The exemplary SiGe ML film stack 900 is unbiased (e.g., no potential is applied). The first energy band gap diagram 951 indicates energy bands prior to Fermi level alignment. The second energy band gap diagram 953 indicates energy bands after Fermi level alignment. The first 907, third 911, and fifth 915 SiGe layers with high Ge content and neither boron nor carbon doping are the three 2DHG layers. Each of the three 2DHG layers aligns with E_{G4} energy levels which are locations of the quantum wells (QW).

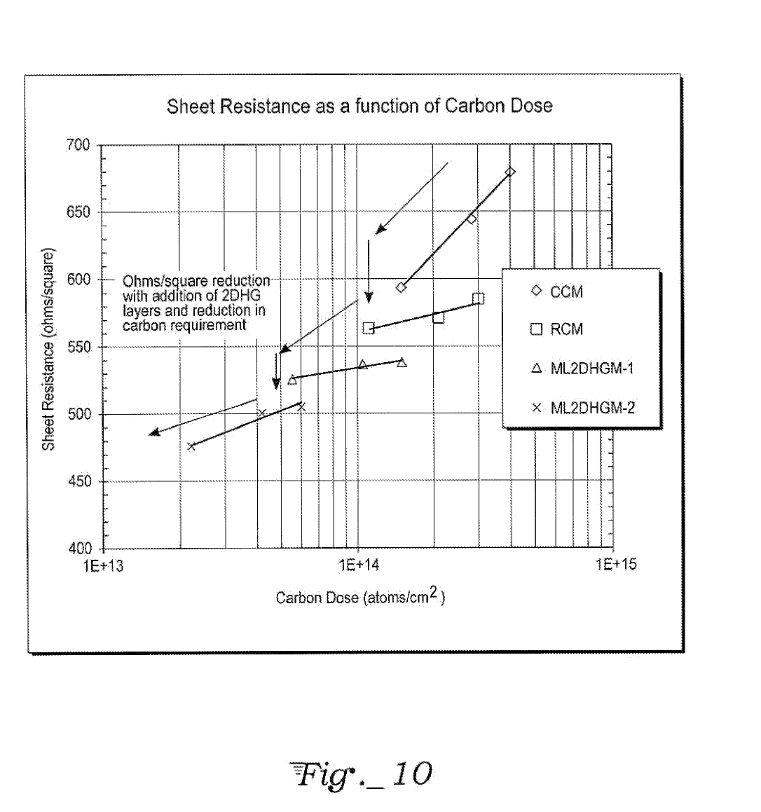

A benefit of ML layers for a reduction in sheet resistance (and ultimately the base resistance in HBTs) is quantified with reference to FIG. 10. Results depicted in FIG. 10 are from a structure that is identical in construction to that shown in the exemplary SiGe ML film stacks 200, 700 of FIG. 2 and FIG. 7. These results provide a comparison of (1) a standard SiGe film doped with carbon throughout, known as the complete carbon method (CCM), (2) SiGe film with the remote carbon method (RCM), and (3) an ML SiGe film with a 2DHG layer, referred to as a multi-layer 2DHG method (ML2DHGM). The results of the ML2DHGM are from the film depicted in the exemplary SiGe ML film stack 700 (FIG. 7), which contains a boron doped SiGe layer sandwiched between two 2DHG layers (undoped SiGe).

The remote carbon method discussed above in a pending case illustrates that carbon may be located outside of a boron doped region and still be effective in mitigating boron outdiffusion. Additionally, a total dose of carbon required to mitigate boron diffusion is reduced. The remote carbon method therefore further enhances the sheet resistances (i.e., reduces the sheet resistance) due to a reduction in alloy scattering. The reduction in alloy scattering results in an increased hole carrier mobility.

FIG. 10 further illustrates adding undoped SiGe layers between the boron doped SiGe and the SiGeC layers (see FIGS. 2 and 7), reduces the sheet resistance even further. These results are for the CCM, RCM and the ML2DHG film depicted in FIG. 7. In the graph of FIG. 10, the difference between ML2DHG-1 and ML2DHG-2 is only due to the width of the 2DHG layer. The total film thickness for all films is approximately 25 nm. The CCM layer has carbon throughout. The RCM layer has carbon only in SiGeC spacer regions. A SiGeB layer approximately 8.3 nm thick is sandwiched between the SiGeC layers (also approximately 8.3 nm thick in a specific exemplary embodiment of FIG. 4).

The ML2DHG-1 layer of FIG. 7 is fabricated with a central SiGeB layer of approximately 8.3 nm in thickness and sandwiched between undoped SiGe (2DHG or QW layers). The undoped SiGe and SiGeC layers are each approximately 4 nm in thickness. The ML2DHG-2 layer of FIG. 7 is also fabricated with a central SiGeB layer of approximately 8.3 nm in thickness. The central SiGeB is sandwiched between undoped SiGe (2DHG or QW layers) of approximately 6 nm thickness each. The SiGeC layers are 2 nm in thickness.

### Processing of Si/SiGe/Si Multi-Layers for HBT and Other Device Applications

Exemplary embodiments described relate specifically to a heterojunction bipolar transistor (HBT). However, techniques described herein perform similarly for other applications such as channel regions of MOSFET, FINFET, HEMT, and other device types. Also, these layers can be extended to many repetitions. For instance, the structure of FIG. 9 contains three undoped SiGe layers (no carbon, no boron), two SiGeC layers (no boron), and two SiGeB layers (no carbon). This type of structure can be carried out to other structures which contain ‘n’ undoped SiGe layers, and ‘n−1’ SiGeC and SiGeB layers. This type of implementation would be useful in fabricating, for example, a quantum cascade laser.

An exemplary method of processing the structures is to form various layers using low-pressure chemical vapor deposition (LPCVD). However, many other methods will work such as, for example, ultrahigh vacuum CVD (UHVCVD), molecular beam epitaxy (MBE), rapid thermal CVD (RTCVD), plasma enhanced CVD (PECVD), and atomic-layer deposition (ALD). These and other methods may all be, singly or in combination, employed as well.

### Surface Preparation and Seedlayer Growth

An exemplary method for surface preparation and seedlayer growth begins with a surface pre-clean in a wet bath of dilute hydrofluoric acid diluted with de-ionized water (HF with DI). The pre-clean is typically performed prior to film growth to ensure a clean surface. The surface pre-clean removes native oxides and other surface contamination. The surface is usually dried with isopropyl alcohol (IPA) after pre-clean.

A prebake step, for example at a temperature greater than 900° C. , is typically employed prior to seedlayer growth. However, depending on substrates and technologies employed, prebake temperatures less than 900° C. may also be utilized. The prebake is typically carried out in a hydrogen ambient but inert gas ambient environments may also be utilized. In a specific exemplary method, a hydrogen containing dopant gas may also be utilized, such as arsine (AsH₃). Arsine can be utilized to provide a sharp n-type dopant profile at the base-collector junction of an HBT.

Seedlayer growth may be formed from silicon by thermal and/or chemical decomposition of a precursor such as silane (SiH₄). However, other silicon precursors such as disilane (Si₂H₆), dichlorasilane (SiH₂Cl₂), or other silicon containing precursors may be readily utilized as well. A skilled artisan recognizes that silicon is not the only acceptable seedlayer material. Compounds of SiGe, SiGeC, and pure Germanium (Ge) function properly especially when combined with a layer transfer process such as that used in contemporary silicon-on-insulator (SOI) fabrication facilities. Germanium precursors, such as germane (GeH₄), may be utilized, or any Ge containing precursor that can be chemically and/or thermally decomposed. Additionally, chlorine containing precursors are particularly useful for selective epitaxy and selective polysilicon applications. Processing temperatures in the range of 850° C. to 1000° C. obtain good epitaxial growth. However, temperatures less than 850° C. can be used. Seedlayer thicknesses commonly employed are between 10 nm and 100 nm, but are not limited to this range.

Process pressures are usually between 50 Torr and 120 Torr. Pressures less than 50 Torr and greater than 120 Torr may also be used. Common carrier gases (or ambient) include hydrogen (H₂) or inert gases such as helium (He), argon (Ar), neon (Ne), and Xenon (Xe). Also, any blend of the above mentioned carrier gases may be utilized. For example, hydrogen and helium can be utilized simultaneously as the carrier gas mix.

The seedlayer may also contain an n-type dopant such as arsenic and/or phosphorous. Precursors in this case are usually arsine (AsH₃) and/or phosphine (PH₃) respectively but skilled artisans recognize that other precursors may be used as well. If the seedlayer is doped n-type, a range of dopant concentrations is typically from 5E17 atoms/cm³ to 5E18 atoms/cm³. However, some technological considerations may require less than 5E17 atoms/cm³ or more than 5E18 atoms/cm³ depending on performance targets for BV_{CB0}, Early voltage (V_{AF}), I_{CB0} (reverse bias leakage), or other target parameters. Peak dopant concentrations may be determined by secondary ion mass spectrometry (SIMS) or other techniques known in the art.

### Design Guidelines for Silicon-germanium Multi-Layers

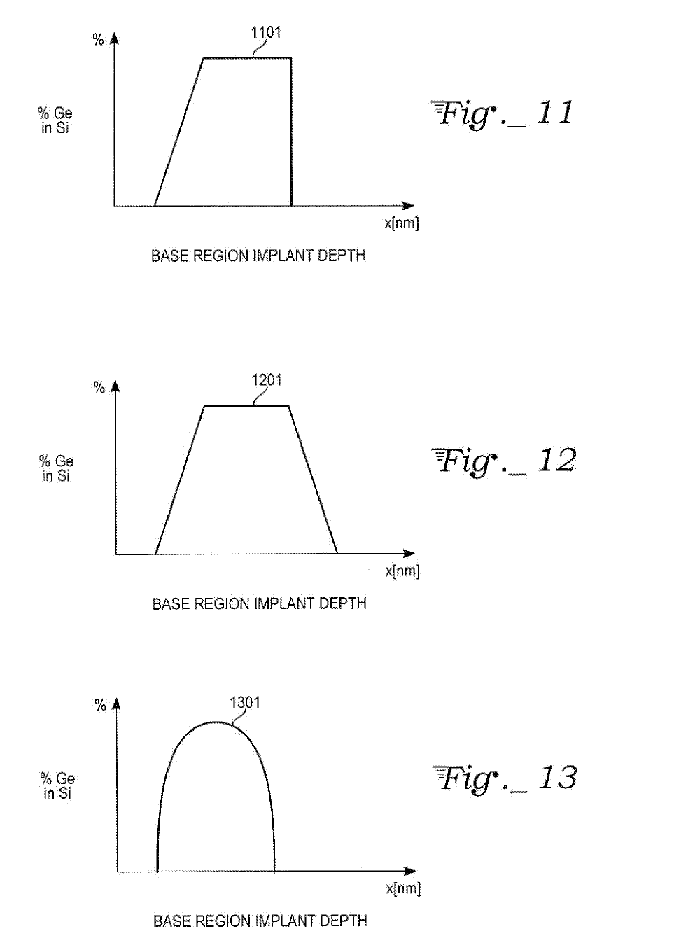

SiGe, SiGeC, SiGeB, and/or SiGeC:B layers may be formed by LPCVD or other techniques as described herein or by other methods known in the art. These layers can be arranged in many combinations such as, but not limited to those illustrated in FIGS. 2-9 above. Additionally, the exemplary embodiments of FIGS. 2-9 are defined by a box profile; other profiles are beneficial as well depending upon target performance characteristics selected or desired. For example, FIGS. 11-15 indicate various types of germanium profiles for percentage of germanium in silicon as a function of base region depth. Although each of the figures explicitly recites an implant depth, a skilled artisan would recognize that other methods may be used to produce an increased Ge concentration profile or gradient within the silicon as well.

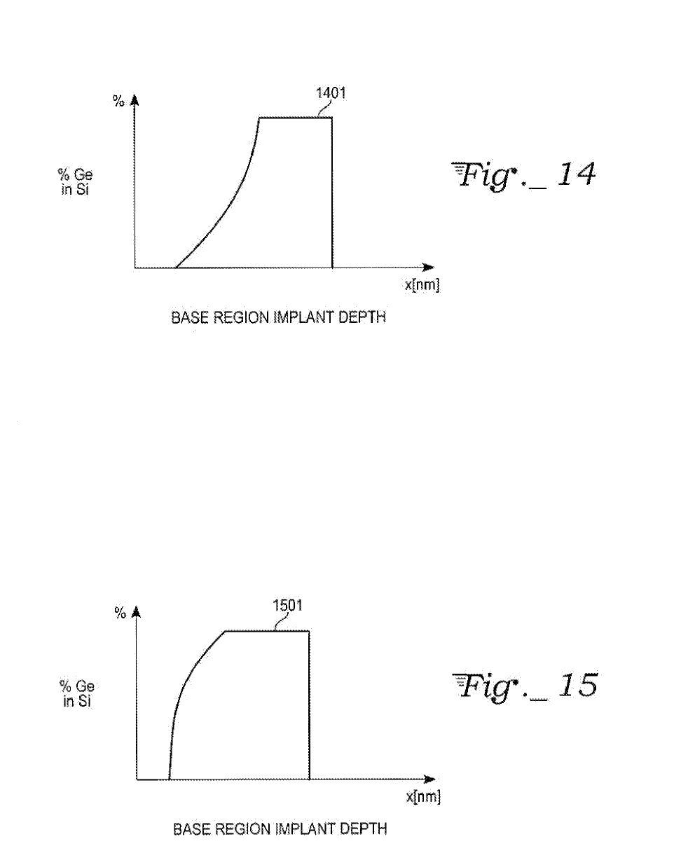

FIG. 11 is a box plus grade profile 1101. The box plus grade profile 1101 provides a built-in drift field to enhance electron transport across the base region of a fabricated device. FIG. 12 is a trapezoidal profile 1201 and FIG. 13 is a curved profile 1301. The trapezoidal profile 1201 and the curved profile 1301 each also provide a built-in drift field to enhance electron transport across the base region of a fabricated device. FIGS. 14 and 15 each indicate profiles with curvature. FIG. 14 is a box plus concave ramp section profile 1401 and FIG. 15 is a box plus convex ramp section 1501. These and other Ge profiles are known in the art. A skilled artisan also recognizes various profiles may be applied depending upon particular design characteristics and parameters desired for a device.

In a specific exemplary embodiment, the concentration of Germanium for various SiGe ML is between 15% and 25% for thicknesses ranging from approximately 50 nm to 25 nm, respectively. Depending upon selected device characteristics, Ge fractions of less than 15% and greater than 25% may also be used. However, there is a limit to how much Ge can be added to the Si lattice before excess strain relaxation and gross crystalline defects occur. A critical thickness, h_{c}, of a SiGe layer that is lattice matched to underlying silicon is primarily a function of (1) percentage of Ge employed; (2) SiGe film thickness; (3) a thickness of a subsequent cap layer; (4) a temperature employed in HBT film-stack processing; and, (5) a temperature of any thermal anneals following a SiGe deposition. Above the critical thickness, h_{c}, the SiGe film is in a metastable and/or unstable region which implies it relaxes readily with a large enough application of thermal energy. Therefore, a degree of metastability is largely a function of percent Ge, SiGe layer thickness, cap layer thickness, and process induced strain due to thermal energy. The critical thickness of the strain-compensated metastable SiGe base region is determined based on atomic percentage of Ge within an upper and lower bound of a metastable region. The critical thickness determination is based on historical work of People/Bean and Matthews/Blakesly, and is known in to one of skill in art.

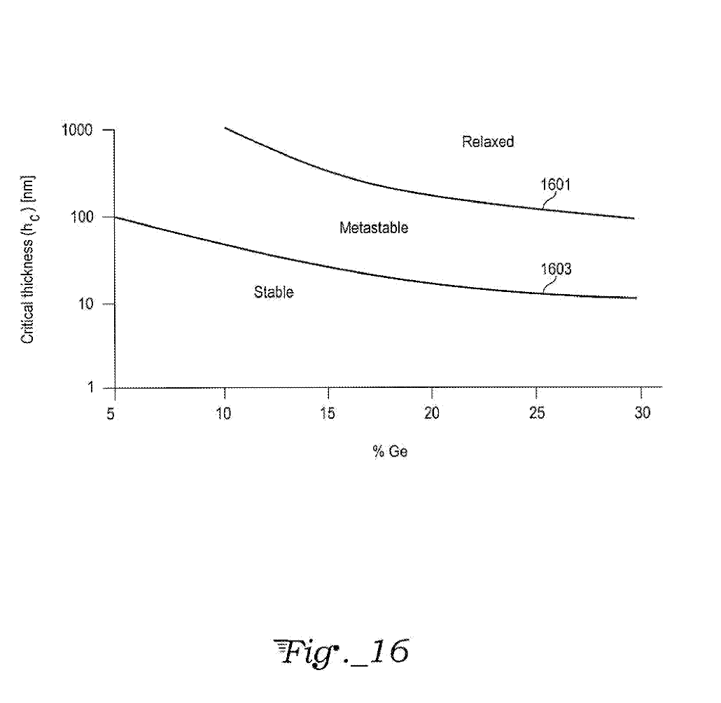

FIG. 16 is a graph indicating critical thickness of pseudomorphic SiGe on silicon as a function of either percentage or mole fraction of germanium in the silicon lattice. As an example, FIG. 16 shows that for a film with 20% Ge, the critical thickness, h_{c}, according to the People/Bean curve 1603 as defined by the bottom edge of the metastable region and is approximately 20 nm, while a film with 28% Ge has a critical thickness, h_{c}, of only 9 nm. Therefore, to grow a fully “strain compensated” film with 28% Ge that is also 20 nm thick, carbon may be added to reduce the lattice parameter and strain compensate 8% of Ge. The addition of 1% of carbon throughout the SiGe lattice of a 20 nm, 28% Ge film reduces the strain to a level that approximates that of a 20 nm, 20% Ge film. The Matthews/Blakesly curve 1601 is defined by the upper edge of the metastable region. Graphs such as FIG. 16 which indicate regions of film stability are therefore useful to gauge an amount of Ge and the film thickness that work safely for a particular device application.

A combined thickness of all SiGe Multi-layers taken as a single film stack in embodiments defined above is generally 25 nm to 50 nm. However, based on provisos and considerations given above, thickness ranges less than 25 nm and greater than 50 nm can be useful. Individual multi-layers can be, for example, 5 nm to 10 nm in thickness as determined by X-ray diffraction or other film thickness determination techniques.

### Processing Guidelines for Silicon-germanium Multi-Layers

Typical film growth conditions include deposition temperatures of 550° C. to 650° C. in a pressure range of 50 Torr to 120 Torr. However, temperatures and pressures outside of these ranges could readily be employed and are partially dependent upon deposition techniques employed. For example, ALD processes are frequently used at temperatures of 300° C. or less. Silane and germane may be used as the silicon and germanium precursors, although other Si and Ge containing precursors may be used provided they are chemically and/or thermally decomposable. Carrier gases and/or mixtures are the same as disclosed for the seed layer growth described above.

Methylsilane (CH₃SiH₃) is a particular carbon precursor that has been used successfully although any thermally and/or chemically decomposable carbon precursor will function properly. The carbon concentration must be high enough to prevent excessive boron outdiffusion. For example, a peak concentration of 1.2E20 atoms/cm³ of boron requires a peak carbon concentration of approximately 1E20 atoms/cm³ to effectively prevent boron outdiffusion. Required carbon and boron concentrations partially depend on the percent of Ge that is added to the Si lattice. Some characterization may be necessary to determine an optimum ratio of carbon to boron to prevent boron outdiffusion and also to attain a targeted base resistance and other device characteristics. The characterization is necessary due to various permutations of factors such as compound semiconductor selected, percentages of elemental components within the compound, dopant levels, and deposition processes and temperatures utilized.

Diborane (B₂H₅) is a particular carbon precursor that has been used successfully although other boron and carbon containing precursors will function properly. In a specific exemplary embodiment, a peak boron concentration range is from approximately 5E19 atoms/cm³ to 1.2E20 atoms/cm³, as measured by SIMS following film growth. However, peak concentrations of less than 5E19 atoms/cm³ and greater than 1.2E20 atoms/cm³ may be utilized to achieve a desired target for base resistance, Early voltage, current gain, fₘₐₓ, or other parameters of interest.

### Fabrication of the Cap Layer

In a SiGe HBT, the cap layer is part of the emitter structure and defines the metallurgical junction placement relative to the Si/SiGe heterojunction. The metallurgical junction placement relative to the Si/SiGe heterojunction also defines the band gap offset ΔE_{G}(0), at the base-emitter heterojunction.

In a specific exemplary embodiment, the cap layer is constructed of silicon using pressure settings, gases, and mixtures similar to those employed in producing the seedlayer. However; processing temperatures in this embodiment are typically between 700° C. and 800° C. Temperatures less than 700° C. and greater than 800° C. may also be useful depending on technology requirements for growth rate, dopant incorporation and activation, and other factors.

The cap layer is typically between 35 nm and 55 nm in thickness but thicknesses less than 35 nm and greater than 55 nm may also be used to tune placement of the metallurgical/heterojunction at the base-emitter side of an HBT. The cap layer is also typically undoped. However, an n-type dopant such as arsenic (As) and/or phosphorous (P) may be used. Arsine and phosphine are typical precursor gases for As and P respectively.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, dopant steps are generally defined herein in terms of implantation procedures (e.g., ion implantation). A skilled artisan will recognize that other dopant techniques, such as diffusion, will also readily product doped-regions in an electronic device.

Also, although process steps and techniques are shown and described in detail, a skilled artisan will recognize that other techniques and methods may be utilized which are still included within a scope of the appended claims. For example, there are frequently several techniques used for depositing a film layer (e.g., chemical vapor deposition, plasma-enhanced vapor deposition, molecular beam epitaxy, atomic layer deposition, atmospheric pressure CVD, etc.). Although not all techniques are amenable to all film types described herein, one skilled in the art will recognize that multiple methods for depositing a given layer and/or film type may be used. Also, although most embodiments are described with specific reference to silicon and germanium compounds, devices fabricated from other Group II-VI or III-V semiconductor compounds such as GaAs, InP, or AlGaAs may benefit from techniques described herein as well. Moreover, the substrate itself may be comprised of a non-semiconducting material, for example, a quartz reticle with a deposited and doped polysilicon layer followed by an anneal step (e.g., rapid-thermal annealing (RTA) or an excimer laser annealing (ELA)). Therefore, a semiconductor substrate could be a non-semiconducting base with a deposited and annealed film on its surface.

Additionally, many industries allied with the semiconductor industry could make use of techniques described herein. For example, a thin-film head (TFH) process in the data storage industry or an active matrix liquid crystal display (AMLCD) in the flat panel display industry could readily make use of the processes and methodologies disclosed. The term “semiconductor” should therefore be recognized as including the aforementioned and related industries.

What is claimed is:

1. A method for fabricating an electronic device, the method comprising:
providing a semiconductor substrate having a first surface;
doping at least a portion of the first surface;
forming a first compound semiconductor film over the first surface of the substrate, the first compound semiconductor film being doped with a first dopant type;
forming a second compound semiconductor film over the first compound semiconductor film; and
forming a third compound semiconductor film over the second compound semiconductor film, the third compound semiconductor film being doped with a second dopant type.

2. The method of claim 1 wherein the first dopant type is selected to be carbon.

3. The method of claim 1 wherein the second dopant type is selected to be boron.

4. The method of claim 1 wherein the second compound semiconductor film is selected to have a high concentration of germanium.

5. The method of claim 1 wherein the first and second dopant types are each selected to be carbon.

6. The method of claim 1 further comprising:
forming a silicon seed layer over the first surface of the semiconductor substrate; and
forming a silicon cap layer over the third compound semiconductor film.

7. The method of claim 1 wherein each of the compound semiconductor films is selected to be silicon-germanium.

8. The method of claim 1 wherein the semiconductor substrate is selected to be silicon.

9. The method of claim 1 further comprising:
forming a fourth compound semiconductor film over the second compound semiconductor prior to forming the third compound semiconductor film;
doping the fourth compound semiconductor film with boron; and
forming a fifth compound semiconductor film over the fourth compound semiconductor film prior to forming the third compound semiconductor film.

10. The method of claim 9 wherein the fourth and fifth compound semiconductor films is each selected to be silicon-germanium.

11. The method of claim 10 wherein the fifth compound semiconductor film is selected to have a high germanium concentration.

12. The method of claim 1 further comprising:
forming a fourth compound semiconductor film over the third compound semiconductor film; and
doping the fourth compound semiconductor film with carbon.

13. The method of claim 12 wherein the fourth compound semiconductor films is selected to be silicon-germanium.

14. The method of claim 1 further comprising:
forming a fourth and a fifth compound semiconductor film prior to and subsequent to forming the second compound semiconductor film; and
doping each of the fourth and fifth compound semiconductor films with boron.

15. The method of claim 14 further comprising forming a sixth compound semiconductor film between the third and fifth compound semiconductor films.

16. The method of claim 15 wherein the sixth compound semiconductor film is selected to be silicon-germanium with a high germanium concentration.

17. The method of claim 1 further comprising forming an elemental semiconductor cap layer over the third compound semiconductor film.

18. A method of fabricating a heterojunction bipolar transistor, the method comprising:
forming a collector region in a substrate, the substrate being selected to have at least an uppermost portion comprised of an elemental semiconductor;
forming a multi-layer base region, formation of the multi-layer base region including steps of:
forming a first silicon-germanium film over the first surface of the substrate, the first silicon-germanium film being doped with a first dopant type;
forming a second silicon-germanium film over the first silicon-germanium film, the second silicon-germanium film selected to have a high concentration of germanium; and
forming a third silicon-germanium film over the second silicon-germanium film, the third silicon-germanium film being doped with a second dopant type; and
forming an emitter region from an elemental semiconductor layer over the third silicon-germanium film.

19. The method of claim 18 wherein the first dopant type is selected to be carbon.

20. The method of claim 18 wherein the second dopant type is selected to be boron.

21. The method of claim 18 wherein the first and second dopant types are each selected to be carbon.

22. The method of claim 18 further comprising forming a semiconductor seed layer over the substrate.

23. An electronic device comprising:
a substrate having at least an upper portion being comprised of a semiconductor material;
a first doped compound semiconductor film disposed over the upper portion of the substrate;
a second compound semiconductor film disposed over the first compound semiconductor film, the second compound semiconductor film configured to act as a quantum well layer;
a third doped compound semiconductor film disposed over the second compound semiconductor film; and
a cap layer comprised of a semiconductor material.

24. The electronic device of claim 23 wherein each of the compound semiconductor films is substantially comprised of silicon-germanium.

25. The electronic device of claim 24 wherein the second compound semiconductor film has a high concentration of germanium.

26. The electronic device of claim 23 further comprising an elemental semiconductor seed layer disposed between the upper portion of the substrate and the first doped compound semiconductor film.

27. The electronic device of claim 23 wherein the dopant used in each of the first and third compound semiconductor films is carbon.

28. The electronic device of claim 23 wherein the upper portion of the substrate and the cap layer are each comprised of silicon.

29. A heterojunction bipolar transistor comprising:
a collector layer made substantially of an elemental semiconductor, the collector layer being contained in at least an upper portion of a substrate;
an emitter layer made substantially of an elemental semiconductor; and
a base multi-layer located between the emitter layer and the collector layer and comprised substantially of:
a first doped silicon-germanium layer disposed over the upper portion of the substrate;
a second silicon-germanium layer disposed over the first silicon-germanium layer, the second silicon-germanium layer configured to act as a quantum well layer; and
a third doped silicon-germanium layer disposed over the second silicon-germanium layer.

30. The electronic device of claim 29 wherein the second silicon-germanium layer has a high concentration of germanium.

31. The electronic device of claim 29 further comprising an elemental semiconductor seed layer disposed between the upper portion of the substrate and the first doped silicon-germanium layer.

32. The electronic device of claim 29 wherein the dopant used in each of the first and third silicon-germanium layers is carbon.

33. The electronic device of claim 29 wherein the upper portion of the substrate and the emitter layer are each substantially comprised of silicon.
